(19) United States
(12) Patent Application Publication
(10) Pub. No.: US 2024/0096874 A1
(43) Pub. Date: Mar. 21, 2024

(54) TRIGGER SILICON CONTROLLED RECTIFIER

(71) Applicant: GlobalFoundries U.S. Inc., Malta, NY (US)

(72) Inventors: Anindya NATH, Essex Junction, VT (US); Alain F. LOISEAU, Williston, VT (US); Souvick MITRA, Essex Junction, VT (US)

(21) Appl. No.: 17/945,348

(22) Filed: Sep. 15, 2022

(51) Int. Cl. H01L 27/02

(52) U.S. Cl. CPC H01L 27/0262

(57) ABSTRACT

The present disclosure relates to a structure including a trigger element within a semiconductor-on-insulator (SOI) substrate, and a silicon controlled rectifier (SCR) under a buried insulator layer of the SOI substrate. The trigger element is between an anode and a cathode of the SCR.

### BACKGROUND

The present disclosure relates to semiconductor structures and, more particularly, to a trigger silicon controlled rectifier (SCR) circuit in a bulk region of a semiconductor on insulator (SOI) material and methods of manufacture and operation.

A silicon controlled rectifier (SCR) or semiconductor controlled rectifier is a four-layer solid-state current-controlling device. SCRs are unidirectional devices (i.e., can conduct current only in one direction) and are triggered normally by a positive current going into the gate structure. SCRs are mainly used in devices where the control of high power, possibly coupled with high voltage, is required, e.g., as power regulators and motor controls.

Similarly, a diode is an electrical component that allows the flow of current in only one direction. Typically, a large radio-frequency (RF) swing causes junction breakdown, poor voltage scaling, and harmonics distortion in bulk string diodes when used as electrostatic discharge (ESD) protection for RF-switches. Also, relying on the switch self-protection often time results in lower ESD protection levels than desired. Further, known circuits may include trigger diodes built in semiconductor on insulator (SOI) and laterally connected with the SCR in the bulk region.

### SUMMARY

In an aspect of the disclosure, a structure comprises: a trigger element within a semiconductor-on-insulator (SOI) substrate; and a silicon controlled rectifier (SCR) under a buried insulator layer of the SOI substrate. The trigger element is between an anode and a cathode of the SCR.

In an aspect of the disclosure, a circuit comprises: a silicon controlled rectifier (SCR) below a buried insulator layer; and a trigger element including a single crystalline semiconductor material above the buried insulator layer. A plurality of doped regions surround the single crystalline semiconductor material.

In an aspect of the disclosure, a method comprises: forming a trigger element within a silicon-on-insulator (SOI); and forming a silicon controlled rectifier (SCR) under a buried oxide (BOX) layer. The trigger element is between an anode and a cathode of the SCR.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIGS. 1A-1F show structures of the trigger silicon controlled rectifier (SCR), amongst other features, and respective fabrication processes in accordance with aspects of the present disclosure.

FIGS. 2-4 show a field effect transistor (FET) triggered SCR under a buried oxide (BOX) in accordance with aspects of the present disclosure.

FIG. 5 shows a circuit schematic corresponding to the structures of FIGS. 2-4 in accordance with aspects of the present disclosure.

FIGS. 6-8 show a grounded gate (GG) electrostatic device NMOS (ESDNMOS) triggered SCR in accordance with additional aspects of the present disclosure.

FIG. 9 shows a circuit schematic corresponding to the structures of FIGS. 6-8 in accordance with aspects of the present disclosure.

FIGS. 10-12 show a silicon on insulator (SOI) diode triggered SCR under the BOX in accordance with aspects of the present disclosure.

FIG. 13 shows a circuit schematic corresponding to the structures of FIGS. 10-12 in accordance with aspects of the present disclosure.

### DETAILED DESCRIPTION

The present disclosure relates to semiconductor structures and, more particularly, to a trigger silicon controlled rectifier (SCR) circuit in a bulk region or a semiconductor on insulator (SOI) material and methods of manufacture. In the present disclosure, a SCR is built in a substrate region (e.g., below a buried oxide (BOX) layer) and a single crystal semiconductor trigger element is built using the SOI and between an anode and cathode of the SCR. Advantageously, the trigger SCR circuit is area efficient (e.g., 20% smaller area) due to vertical integration, eliminates a trigger diode's Darlington effect, and does not need any extra mask or process changes in comparison to known circuits.

In more specific embodiments, the present disclosure prevents the Darlington effect by having a single crystalline trigger element in the SOI and on top of the SCR. In this way, the present disclosure prevents a Darlington effect in vertical pnp/npn devices which, in turn, prevents scaling behavior (e.g., due to higher leakage, high power dissipation due to high saturation voltage, lower switching speed, etc.) In embodiments, the trigger SCR circuit includes a vertically stacked diode-trigger SCR. Further, the trigger diodes are polysilicon (i.e., gate material) and are vertically stacked on the top of the SCR. In addition, an entirety of the trigger SCR circuit is built in bulk semiconductor material or in bulk semiconductor material on a trap-rich silicon layer.

The trigger silicon controlled rectifier (SCR) circuit of the present disclosure may be manufactured in several ways using a number of different tools. In general, though, the methodologies and tools are used to form structures with dimensions in the micrometer and nanometer scale. The methodologies, i.e., technologies, employed to manufacture the trigger silicon controlled rectifier (SCR) circuit of the present disclosure have been adopted from integrated circuit (IC) technology. For example, the structures are built on wafers and are realized in films of material patterned by photolithographic processes on the top of a wafer. In particular, the fabrication of the trigger silicon controlled rectifier (SCR) circuit uses three basic building blocks: (i) deposition of thin films of material on a substrate, (ii) applying a patterned mask on top of the films by photolithographic imaging, and (iii) etching the films selectively to the mask.

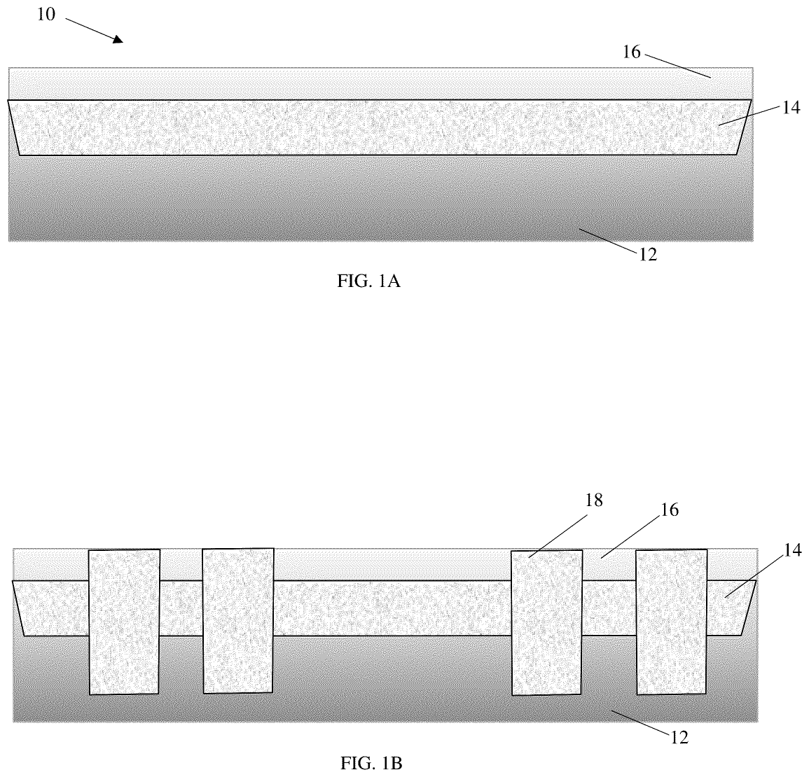

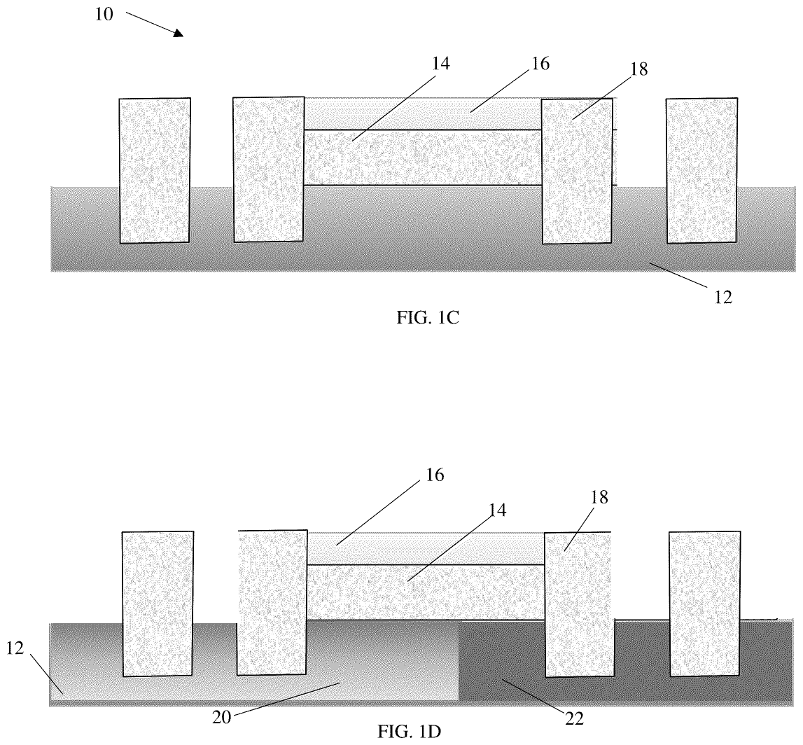

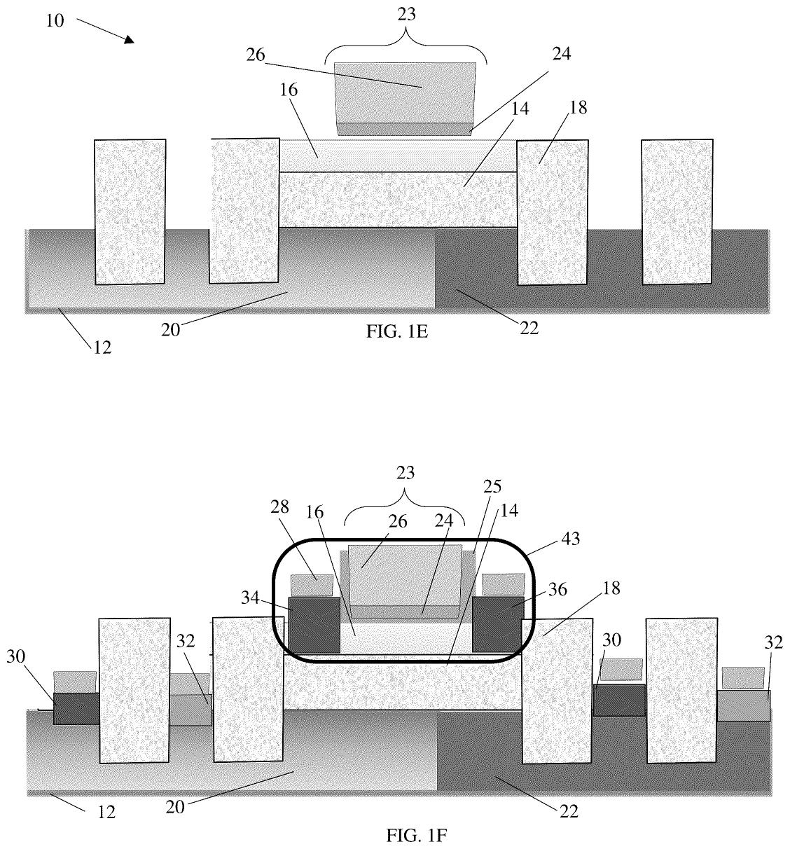

FIGS. 1A-1F show structures of the trigger silicon controlled rectifier (SCR), amongst other features, and respective fabrication processes in accordance with aspects of the present disclosure. In FIG. 1A, a structure 10 includes a handle substrate 12, a buried insulator layer 14, e.g., buried oxide (BOX), on the handle substrate 12, and a semiconductor layer 16 on the insulator layer 14. The handle substrate 12 and semiconductor layer 16 may be composed of any suitable semiconductor material including, but not limited to, Si, SiGe, SiGeC, SiC, GaAs, InAs, InP, and other III/V or II/VI compound semiconductors. In embodiments, the semiconductor layer 16 may be a single crystalline layer of Si.

In FIG. 1B, shallow trench isolation (STI) structures 18 may be formed in the handle substrate 12, the insulator layer 14, and the semiconductor layer 16 using conventional lithography, etching and deposition methods known to those of skill in the art. For example, a resist formed over the semiconductor layer 16 is exposed to energy (light) to form a pattern (opening). An etching process with a selective chemistry, e.g., reactive ion etching (RIE), will be used to transfer the pattern from the resist layer to form one or more trenches in the handle substrate 12, the insulator layer 14, and the semiconductor layer 16. Following removal of the resist layer using a conventional stripping method such as oxygen ashing, an insulating material, e.g., SiO₂, may be deposited within the trenches using conventional deposition methods, e.g., CVD. A planarization process, e.g., chemical mechanical planarization (CMP) may be used to remove any of residual material on the semiconductor layer 16.

In FIG. 1C, an etching process may be used to remove portions of the insulator layer 14 and the semiconductor layer 16 to expose portions of the handle substrate 12. In embodiments, the etching process includes a lithography process followed by a RIE process as is known in the art. In this embodiment, a resist or hardmask will protect part of the semiconductor layer 16 between the inner shallow trench isolation structures 18.

In FIG. 1D, an N-well 20 and a P-well 22 may be formed by conventional ion implantation processes. For example, the N-well 20 and the P-well 22 may be formed by introducing a concentration of different dopants of opposite conductivity type in the handle substrate 12. In embodiments, respective patterned implantation masks may be used to define selected areas exposed for the implantations. The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions. The P-well 22 may be doped with p-type dopants, e.g., Boron (B), and the N-well 20 may be doped with n-type dopants, e.g., Arsenic (As), Phosphorus (P) and Sb, among other suitable examples.

In FIG. 1E, a gate structure 23 may be formed on the semiconductor layer 16. For example, a gate dielectric material 24 (e.g., gate oxide) may be formed over the semiconductor layer 16 by a conventional deposition process, e.g., chemical vapor deposition (CVD) process or atomic layer deposition (ALD) or plasma enhanced CVD (PECVD). Further, a gate electrode material 26, e.g., polysilicon, may be formed over the gate dielectric material 24 by conventional deposition processes, e.g., CVD processes. A conventional patterning process may be used to pattern the materials 24, 26 into the gate structure 23 as is known in the art.

In FIG. 1F, sidewalls 25 may be formed on the sides of the gate structure 23. In embodiments, the sidewalls 25 may be formed by deposition of nitride and/or oxide, followed by a conventional anisotropic etching process after an epitaxial growth process or ion implantation process to form source regions 36 and drain regions 34 (e.g., N+ regions). The sidewall material may be used to prevent epitaxial growth on the gate structure 23 during the formation of the source regions 36 and drain regions 34 (and other raised regions, e.g., N+ regions 30 and P+ regions 32).

The N+ regions 30 and P+ regions 32, in addition to the source regions 36 and drain regions 34, may be formed by conventional epitaxial growth processes with an in-situ doping process to form raised doped regions, particularly raised source regions 36 and raised drain regions 34 adjacent to the gate structure 23. Alternatively, the source regions 36, drain regions 34, N+ regions 30 and P+ regions 32 may be formed by ion implantation processes. For example, the regions 30, 32, 34, 36 may be formed by introducing a concentration of different dopants of opposite conductivity type in the handle substrate 12. The P+ regions may include p-type dopants, e.g., Boron (B), and the N+ regions 30 may include n-type dopants, e.g., Arsenic (As), Phosphorus (P) and Sb, among other suitable examples. The insulator layer 14, semiconductor layer 16, gate dielectric material 24, gate dielectric material 26, N+ regions 30, drain region 34, and source region 36 may form a trigger element 43.

A silicide 28 can be formed on the patterned semiconductor materials. As should be understood by those of skill in the art, the silicide process begins with deposition of a thin transition metal layer, e.g., nickel, cobalt or titanium, over fully formed and patterned semiconductor devices (e.g., doped regions and gate structure 23). After deposition of the material, the structure is heated allowing the transition metal to react with exposed silicon (or other semiconductor material as described herein) in the active regions of the semiconductor device (e.g., source, drain, gate contact region) forming a low-resistance transition metal silicide 28. Following the reaction, any remaining transition metal is removed by chemical etching, leaving silicide contacts 28 in the active regions of the device.

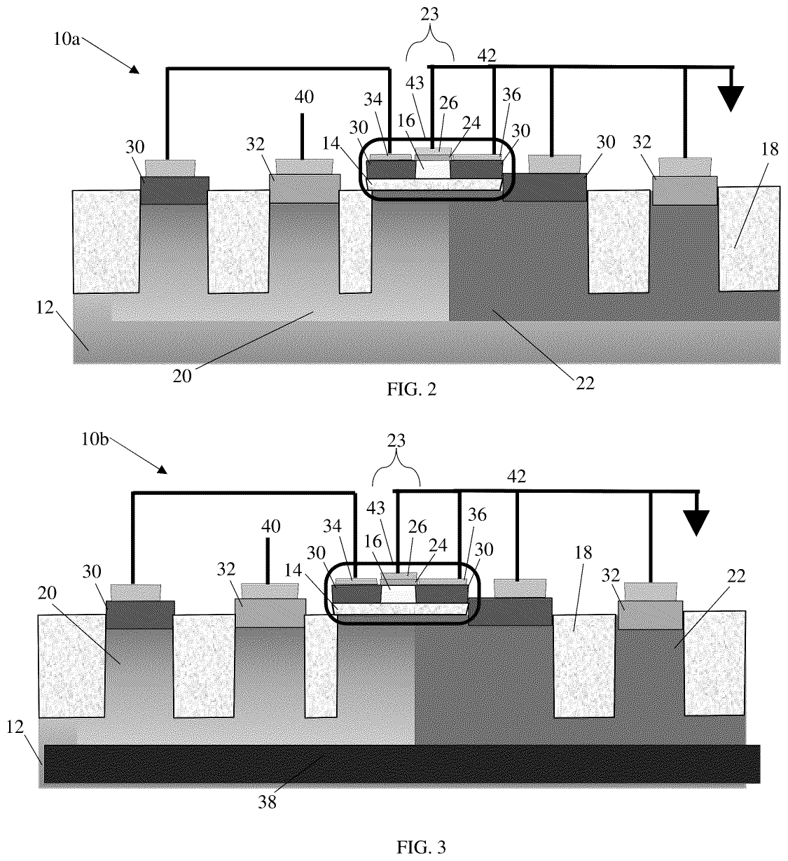

FIGS. 2-4 show field effect transistor (FET) triggered SCRs under a buried insulator layer in accordance with aspects of the present disclosure. In FIGS. 2-4, the FET triggered SCR may have a smaller area due to vertical integration and further is capable eliminating the Darlington effect due to the use of a trigger element 43.

The structure 10a of FIG. 2 includes an anode 40 connected to the P+ region 32 and cathode 42 connected to the gate material (e.g., gate electrode) 26, source region 36, N+ region 30, P+ region 32, and ground. A trigger element 43 (represented by a bounded circle) may include the insulator layer 14, semiconductor layer 16, gate dielectric material 24, gate material 26, two N+ regions 30, drain regions 34, and source regions 36. Furthermore, as shown in FIG. 2, the trigger element 43 may comprise a field effect transistor (FET) (i.e., gate structure 23) on top of the SOI 16, e.g., semiconductor layer 16, and between the anode 40 and cathode 42 of the SCR. Additionally, an N+ region 30 outside of the trigger element 43 is connected to an N+ region 30 inside the trigger element 43. In FIG. 2, the structure 10a has three STI structures 18 on the side of the N-well 20, and two STI structures 18 on the side of the P-well 22. The remaining features are similar to that shown in FIG. 1F.

FIG. 3 shows a structure 10b similar to the structure 10a in FIG. 2 with the addition of a high resistivity layer 38 formed by conventional ion implantation processes within the handle substrate 12. In embodiments, the high resistivity layer 38 may be under and connected to the N-well 20 and the P-well 22. In embodiments, the high resistively layer 38 of the structure 10b may help isolate the SCR from the handle substrate 12.

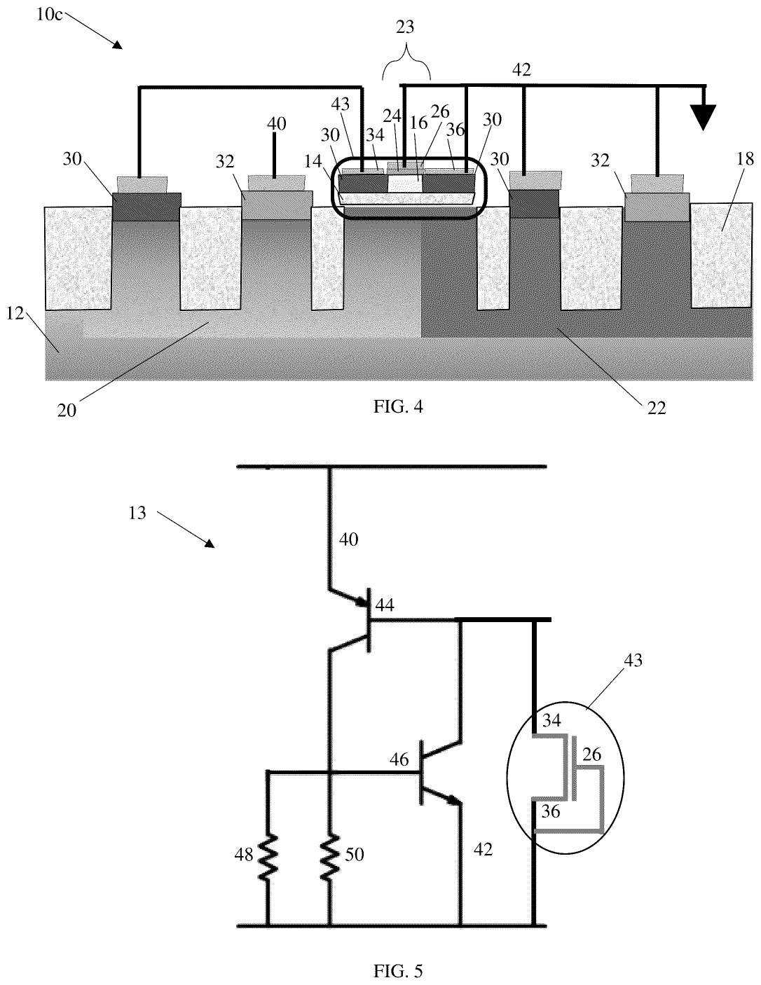

In FIG. 4, a structure 10c includes three STI structures 18 on both sides of the trigger element 43 (e.g., three STI structures 18 on the side of the N-well 20 and three STI structures 18 on the side of the P-well 22). Therefore, the structure 10a in FIG. 2 has a smaller area size in comparison to the structure 10c in FIG. 4. In a further embodiment, the structure 10c may include the high resistivity layer 38 (not shown in FIG. 4). The remaining features are similar to that shown in FIG. 3.

FIG. 5 shows a circuit schematic corresponding to the structures 10a, 10b, and 10c in FIGS. 2-4. In FIG. 5, a circuit schematic 13 includes the anode 40 connected to an emitter of a PNP bipolar junction transistor (BJT) 44. The emitter of a NPN BJT 46 is also connected to the cathode 42. The cathode 42 is connected to ground. The resistors 48 and 50 are representative of the P-well 22 and are connected to ground. The source region 36 of the trigger element 43 is connected to the gate material (e.g., electrode) 26 and ground. In embodiments, the trigger element 43 of FIG. 5 may be an NFET, although the use of a PFET is also contemplated. Further, the SCR may comprise the PNP BJT 44 and the NPN BJT 46.

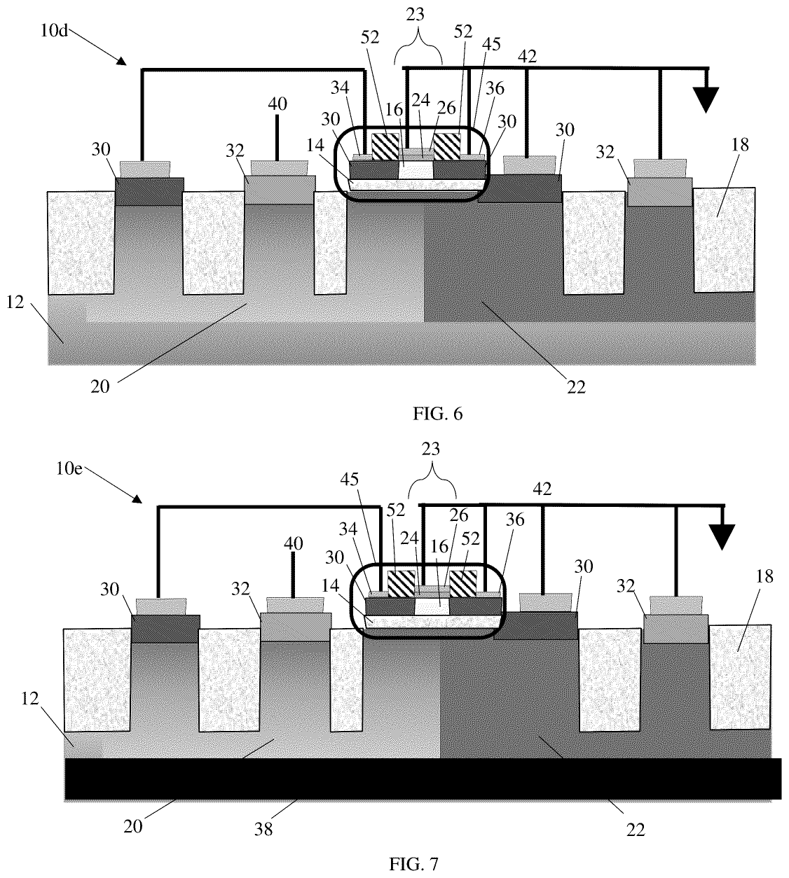

FIGS. 6-8 show a grounded gate (GG) electrostatic device NMOS (ESDNMOS) triggered SCRs. In FIGS. 6-8, the grounded gate (GG) electrostatic device NMOS (ESDNMOS) triggered SCRs may have a smaller area due to vertical integration and also eliminates the Darlington effect due to the use of the trigger element 45.

In FIG. 6, the structure 10d includes a blocking layer 52 on the N+ region 30 and adjacent to the source regions 34 and the drain regions 36 within trigger element 45. The blocking layer 52 may cause portions of the source regions 34 and the drain regions 36 to be unsilicided. In embodiments, the blocking layer 52 may be a nitride or oxide layer which improves the electrical characteristics of the trigger element 45 by increasing an amount of discharge current. Therefore, although the trigger element 45 may have a larger area than the trigger element 43 of FIG. 2, the trigger element 45 may improve electrical characteristics by including the blocking layer 52 adjacent to the source regions 34 and drain regions 36. The structure 10d further includes three STI structures 18 on the side of the N-well 20, and two STI structures 18 on the side of the P-well 22 to decrease its size.

FIG. 7 shows a structure 10e similar to the structure 10d in FIG. 6. In FIG. 7, a high resistivity layer 38 formed by conventional ion implantation processes may be provided within the handle substrate 12, contacting the N-well 20 and the P-well 22. In embodiments, the high resistively layer 38 may help isolate the SCR from the handle substrate 12.

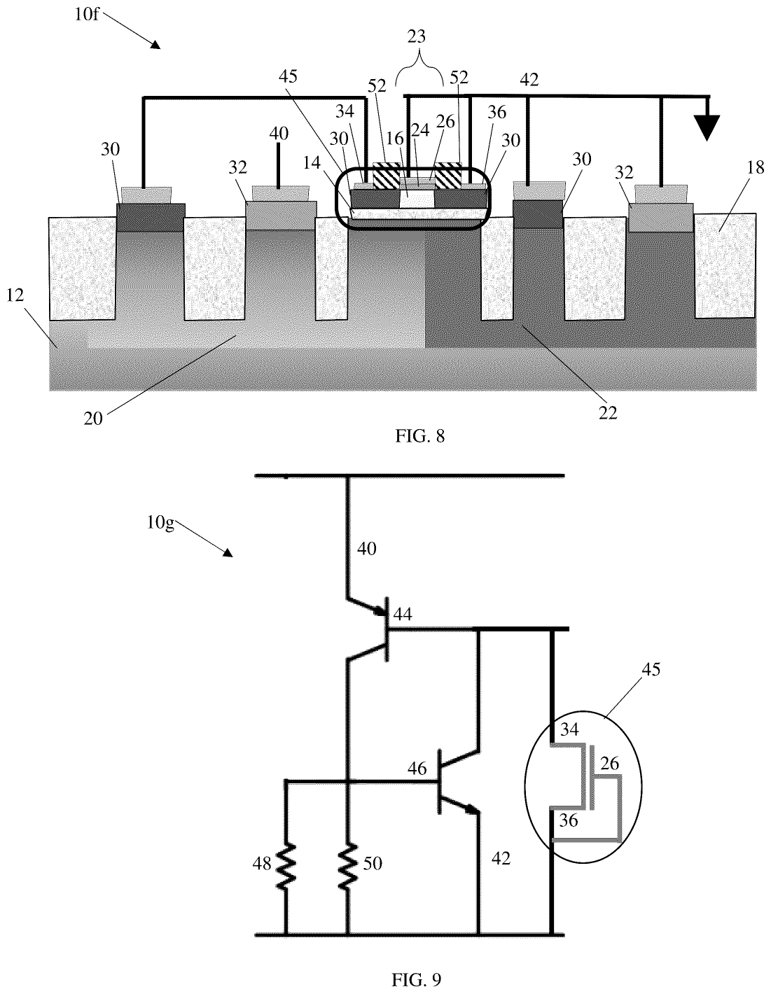

In FIG. 8, the structure 10f has three STI structures 18 on both the side of the N-well 20 and the side of the P-well 22. In further embodiments, the structure 10f in FIG. 8 does not include the high resistivity layer 38 within the handle substrate 12. The remaining features are similar to that shown in FIG. 6.

FIG. 9 shows a circuit schematic corresponding to the structures 10d 10e, and 10f in FIGS. 6-8. In FIG. 9, the circuit schematic 10g includes the anode 40 connected to an emitter of a PNP bipolar junction transistor (BJT) 44. Further, the emitter of a NPN BJT 46 is connected to the cathode 42. The cathode 42 is also connected to ground. The resistors 48 and 50 formed within the P-well 22 are also connected to ground. The trigger element 45 may be a field effect transistor (FET) with the source region 36 connected to the gate material (e.g., gate electrode) 26 and ground. The trigger element 45 of FIG. 9 may be an NFET, although a PFET is also contemplated herein. Further, in FIG. 9, the SCR may comprise the PNP BJT 44 and the NPN BJT 46.

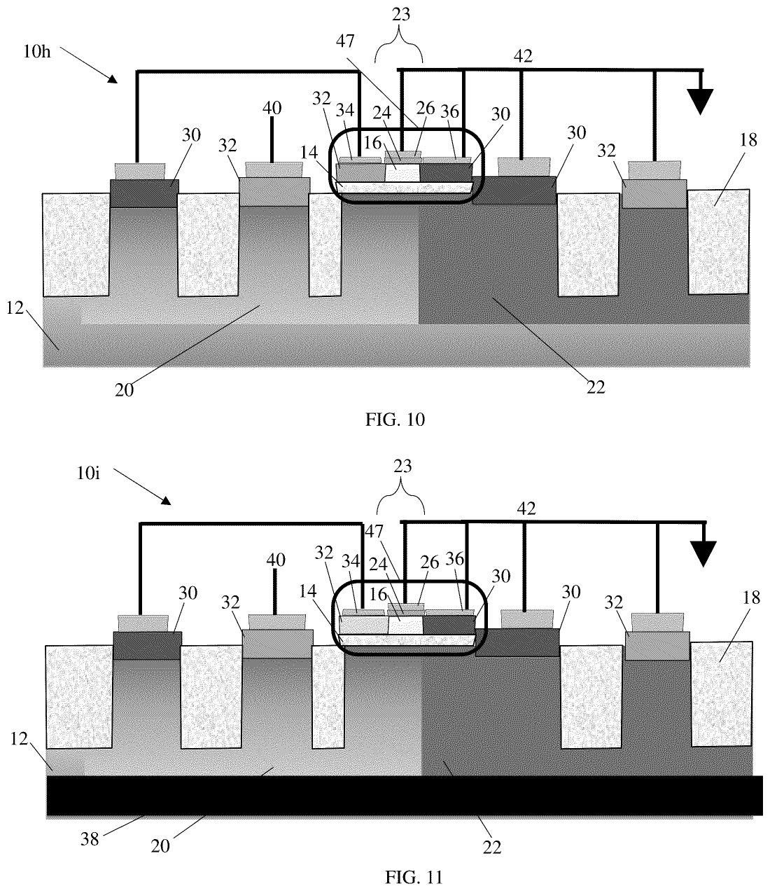

FIGS. 10-12 show a SOI diode triggered SCR under the buried insulator material in accordance with aspects of the present disclosure. In FIGS. 10-12, the silicon on insulator (SOI) diode triggered SCR under the buried insulator layer may have a smaller area due to vertical integration and also is capable of eliminating the Darlington effect due to the use of trigger element 47.

In FIG. 10, the trigger element 47 includes the N+ region 30 and the P+ region 32 in comparison to the trigger element 43 of FIG. 2 which includes only the N+ region 30. In embodiments, the trigger element 47 may comprise a diode on top of the SOI 16 (e.g., semiconductor layer 16) and between the anode 40 and cathode 42 of the SCR. In FIG. 10, the structure 10h has three STI structures 18 on the side of the N-well 20, and two STI structures 18 on the side of the P-well 22.

FIG. 11 shows another structure 10i similar to the structure 10h in FIG. 10. In FIG. 11, though, a high resistivity layer 38 may be formed by conventional ion implantation processes within the handle substrate 12 and in contact with the N-well 20 and the P-well 22. In embodiments, the high resistively layer 38 of the structure 10i may help isolate the SCR from the handle substrate 12.

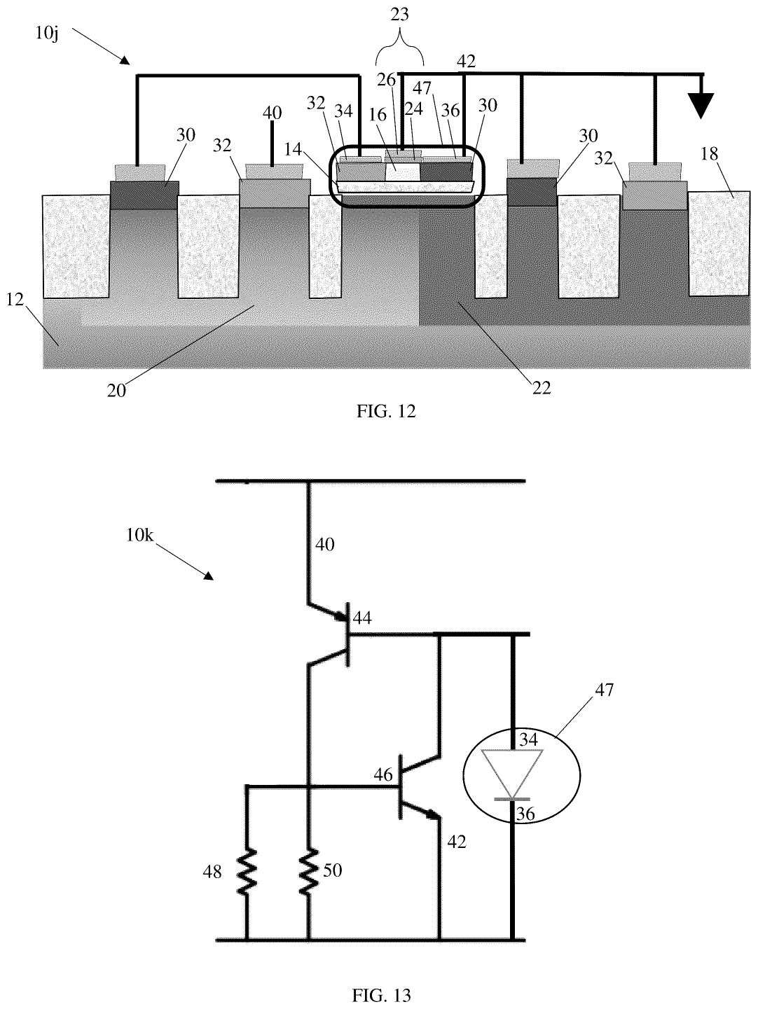

In FIG. 12, the structure 10j includes three STI structures 18 on both sides of the trigger element 47 (e.g., three STI structures 18 on the side of the N-well 20 and three STI structures 18 on the side of the P-well 22). In further embodiments, the structure 10j may include a high resistivity layer 38 (not shown in FIG. 12) within the handle substrate 12.

FIG. 13 shows a circuit schematic corresponding to the structures 10h, 10i, and 10j in FIGS. 10-12. In FIG. 13, a circuit schematic 10k includes the anode 40 connected to an emitter of a PNP bipolar junction transistor (BJT) 44. Further, an emitter of a NPN BJT 46 is connected to the cathode 42. The cathode 42 is also connected to ground in FIG. 13. The resistors 48 and 50 of the P-well 22 are also connected to ground. In FIG. 13, the trigger element 47 may be a diode which includes the drain regions 34, the gate material (e.g., gate electrode) 26, and the source regions 36. The source regions 36 are connected to ground. Further, in FIG. 13, the SCR of the present disclosure may comprise the PNP BJT 44 and the NPN BJT 46.

The trigger silicon controlled rectifier (SCR) circuit may be utilized in system on chip (SoC) technology. The SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also used in embedded systems and the Internet of Things.

The method(s) as described above is used in the fabrication of integrated circuit chips. The resulting integrated circuit chips may be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either surface interconnections and buried interconnections or both surface interconnections and buried interconnections). In any case the chip is then integrated with other chips, discrete circuit elements, and/or other signal processing devices as part of either (a) an intermediate product, such as a motherboard, or (b) an end product. The end product may be any product that includes integrated circuit chips, ranging from toys and other low-end applications to advanced computer products having a display, a keyboard or other input device, and a central processor.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising:
a trigger element within a semiconductor-on-insulator (an) substrate; and
a silicon controlled rectifier (SCR) under a buried insulator layer of the SOI substrate, the trigger element being between an anode and a cathode of the SCR.

2. The structure of claim 1, wherein the anode is connected to a P+ region in an N-well below the buried insulator layer.

3. The structure of claim 1, wherein the cathode is connected to an N+ region in a P-well below the buried insulator layer.

4. The structure of claim 1, wherein the trigger element comprises a first N+ region under a drain region and a second N+ region under a source region, the first N+ region is separated from the second N+ region by the SOI substrate, and the cathode is connected to the second N+ region.

5. The structure of claim 4, wherein the SCR is on a trap-rich layer.

6. The structure of claim 4, wherein portions of the source region and the drain region are unsilicided.

7. The structure of claim 1, further comprising three shallow trench isolation (STI) structures on a side of an N-well below the buried insulator layer.

8. The structure of claim 6, further comprising at least two STI structures on the side of a P-well below the buried insulator layer.

9. The structure of claim 6, wherein the source region and a gate electrode material are connected to an N+ region and a P+ region in a P-well below the buried insulator layer.

10. The structure of claim 1, wherein the trigger element comprises an N+ region under a source region and a P+ region under a drain region, and the cathode is connected to the P+ region.

11. A circuit comprising:
a silicon controlled rectifier (SCR) below a buried insulator layer; and
a trigger element comprising a single crystalline semiconductor material above the buried insulator layer, and further comprising a plurality of doped regions surrounding the single crystalline semiconductor material.

12. The circuit of claim 11, wherein the trigger element is between an anode and a cathode of the SCR.

13. The circuit of claim 12, wherein the anode is connected to a P+ region in an N-well below the buried insulator layer.

14. The structure of claim 12, wherein the cathode is connected to an N+ region in a P-well below the buried insulator layer.

15. The structure of claim 12, wherein the plurality of doped regions comprises at least two N+ regions.

16. The structure of claim 15, wherein a first N+ region of the at least two N+ regions is separated from a second N+ region of the at least two N+ regions by the single crystalline semiconductor material.

17. The structure of claim 15, further comprising a blocking layer adjacent to a drain region and a source region of the trigger element.

18. The structure of claim 11, wherein the trigger element comprises a gate electrode material, a drain region, and a source region.

19. The structure of claim 11, wherein the plurality of doped regions comprises an N+ region and a P+ region.

20. A method comprising:
forming a trigger element within a silicon-on-insulator (SOI); and
forming a silicon controlled rectifier (SCR) under a buried oxide (BOX) layer,
wherein the trigger element is between an anode and a cathode of the SCR.
